(19) United States
(12) Patent Application Publication
(10) Pub. No.: US 2026/0096093 A1
(43) Pub. Date: Apr. 2, 2026

(54) SEMICONDUCTOR DEVICE AND METHOD FOR FABRICATING THE SAME

(71) Applicant: SK hynix Inc., Gyeonggi-do (KR)

(72) Inventor: Min Soo KIM, Gyeonggi-do (KR)

(21) Appl. No.: 19/097,867

(22) Filed: Apr. 2, 2025

(30) Foreign Application Priority Data
Sep. 30, 2024 (KR) 10-2024-0132447

(51) Int. Cl. H10B 12/00

(52) U.S. Cl. CPC H10B 12/485; H10B 12/0335

(57) ABSTRACT

Disclosed are a semiconductor device with improved reliability, and a method for fabricating the semiconductor device. A semiconductor device includes a first impurity region disposed in a substrate; a second impurity region disposed in the substrate and spaced apart from the first impurity region; a bit line contact plug disposed over the first impurity region and having a multi-tapered sidewall; and a storage contact plug disposed over the second impurity region, wherein the multi-tapered sidewall of the bit line contact plug includes at least one inflection point at which a slope changes, and wherein the at least one inflection point is disposed higher than a bottom surface of the storage contact plug.

### CROSS-REFERENCE TO RELATED APPLICATIONS

The present application claims priority under 35 U.S.C 119(a) to Korean Patent Application No. 10-2024-0132447, filed on Sep. 30, 2024, which is incorporated herein by reference in its entirety.

### BACKGROUND

### 1. Field

Various embodiments of the present disclosure relate generally to a semiconductor device, and more particularly, to a semiconductor device including a contact plug, and a method for fabricating the semiconductor device.

### 2. Description of the Related Art

As semiconductor technology advances, the size of individual fine patterns in semiconductor devices is decreasing. Additionally, as integrated circuits become more densely packed, the line widths of these fine patterns get smaller, increasing the complexity of forming fine patterns between neighboring patterns.

### SUMMARY

Embodiments of the present disclosure are directed to a semiconductor device with improved reliability, and a method for fabricating the semiconductor device.

In accordance with an embodiment of the present disclosure, a semiconductor device includes a first contact structure disposed over a substrate, the first contact structure having a multi-tapered sidewall; a line structure including a conductive line disposed over the first contact structure; and a plurality of second contact structures disposed between the line structures.

In accordance with another embodiment of the present disclosure, a semiconductor device includes a first impurity region disposed in a substrate; a second impurity region disposed in the substrate and spaced apart from the first impurity region; a bit line contact plug disposed over the first impurity region and having a multi-tapered sidewall; and a storage contact plug disposed over the second impurity region, wherein the multi-tapered sidewall of the bit line contact plug includes at least one inflection point at which a slope changes, and wherein the at least one inflection point is disposed higher than a bottom surface of the storage contact plug.

In accordance with another embodiment of the present disclosure, a method for fabricating a semiconductor device includes forming a first impurity region and a second impurity region in a substrate; forming a bit line contact hole that exposes the first impurity region and has a multi-tapered sidewall; forming a bit line contact plug that fills the bit line contact hole and includes a lower buried portion contacting the first impurity region and an upper buried portion over the lower buried portion; forming a gap-fill layer in a peripheral area of the lower buried portion of the bit line contact plug; side-recessing a sidewall of the upper buried portion of the bit line contact plug; and forming a storage contact plug that contacts the second impurity region.

These and other features and advantages of the embodiments of present disclosure will become apparent from the following detailed description of embodiments in conjunction to the accompanying drawings.

### BRIEF DESCRIPTION OF THE DRAWINGS

FIG. 1A is a plan view illustrating a semiconductor device in accordance with an embodiment of the present disclosure.

FIG. 1B is a cross-sectional view taken along a line A-A′ shown in FIG. 1A.

FIG. 1C is a cross-sectional view taken along a line B-B′ shown in FIG. 1A.

FIG. 1D is a cross-sectional view illustrating a bit line contact plug.

FIGS. 2A to 2C are cross-sectional views illustrating bit line contact plugs in accordance with other embodiments of the present disclosure.

FIGS. 3 to 15 are cross-sectional views illustrating a method for fabricating a semiconductor device in accordance with embodiments of the present disclosure.

FIGS. 16 to 19 are cross-sectional views illustrating a method for fabricating a semiconductor device in accordance with another embodiment of the present disclosure.

FIGS. 20 to 23 are cross-sectional views illustrating a method for fabricating a semiconductor device in accordance with another embodiment of the present disclosure.

### DETAILED DESCRIPTION

Embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure. Hereinafter, the various embodiments of the present disclosure will be described in detail with reference to the attached drawings. The drawings are not necessarily to scale and in some instances, proportions may have been exaggerated in order to clearly illustrate features of the embodiments. When a first layer is referred to as being ‘on’ a second layer or ‘on’ a substrate, it not only refers to a case where the first layer is formed directly on the second layer or the substrate but also a case where a third layer exists between the first layer and the second layer or the substrate.

The following embodiments of the present disclosure suggest a method for securing a spacing distance between a bit line contact plug and a storage contact plug to suppress current leakage.

In order to secure a spacing distance between the storage contact plug and a cusp (or inflection point) of a particular portion of the bit line contact plug, a two-step etching process may be performed during a series of processes of forming a bit line contact hole and the bit line contact plug.

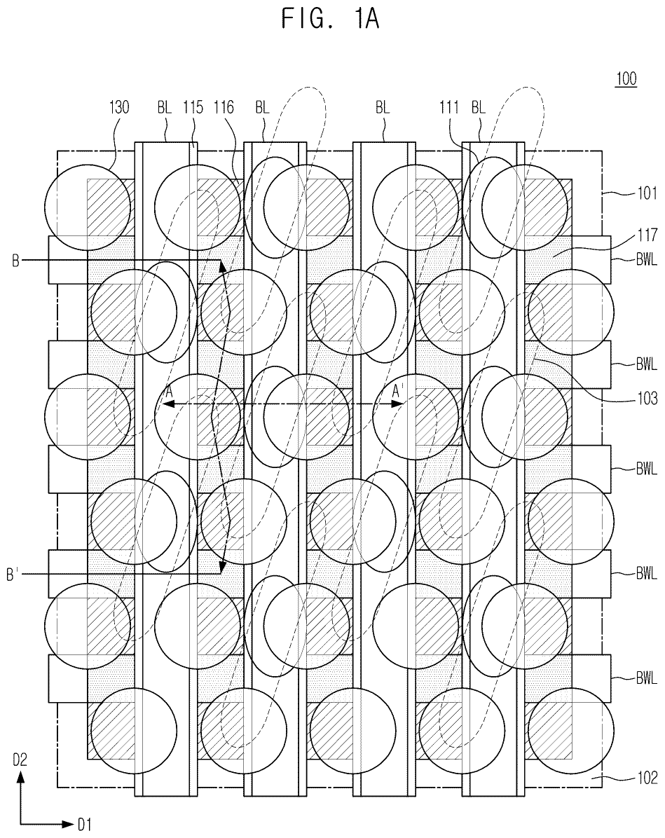

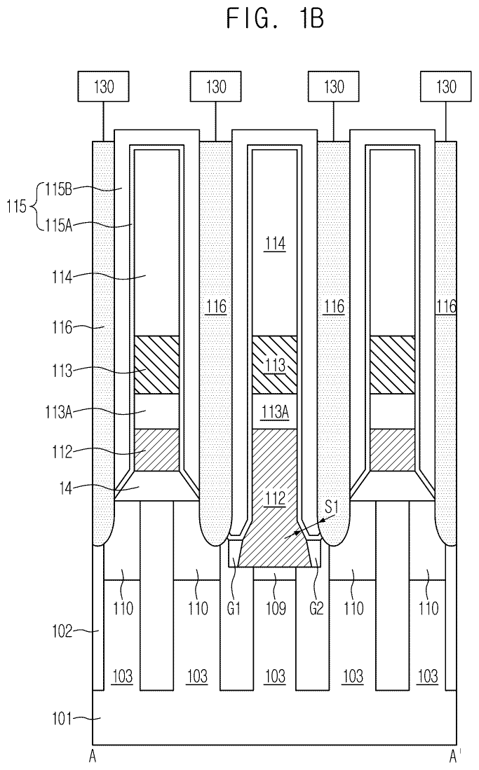

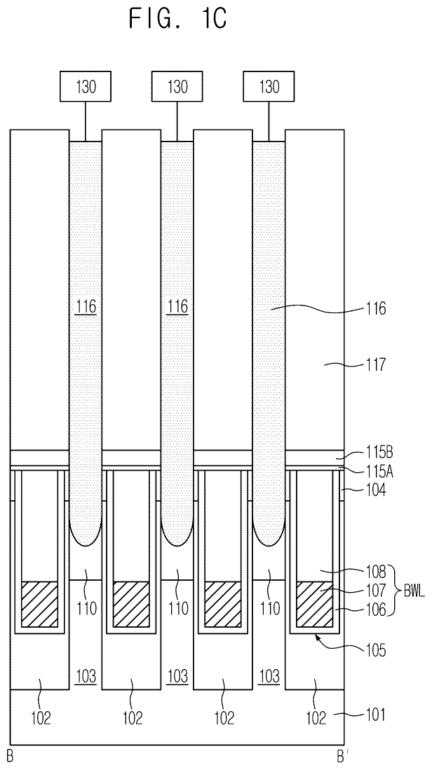

FIG. 1A is a plan view illustrating a semiconductor device 100 in accordance with an embodiment of the present disclosure. FIG. 1B is a cross-sectional view taken along a line A-A′ shown in FIG. 1A. FIG. 1C is a cross-sectional view taken along a line B-B′ shown in FIG. 1A. FIG. 1D is a cross-sectional view illustrating the bit line contact plug.

Referring to FIGS. 1A to 1D, the semiconductor device 100 may include a line structure BL including a plurality of first conductive patterns 113 over a substrate 101, a plurality of second conductive patterns 116 formed between the line structures BL, and plug isolation layers 117 formed between the line structures BL and the second conductive patterns 116. The first conductive patterns 113 may include a bit line 113, and the line structure BL may include a bit line structure BL. The second conductive patterns 116 may include storage contact plugs 116.

According to another embodiment of the present disclosure, the semiconductor device 100 may include a first contact structure 112 formed over the substrate 101 and having a multi-tapered sidewall, a line structure BL including a conductive line over the first contact structure 112, and a plurality of second contact structures 116 formed between the line structures BL. The first contact structure 112 may include a bit line contact plug 112, and the second contact structure 116 may include a storage contact plug 116. The multi-tapered sidewall may be referred to as a step-shaped tapered sidewall.

The semiconductor device 100 may include a plurality of memory cells. Each of the memory cells may include a cell transistor including a buried word line structure BWL, and a bit line 113.

An isolation layer 102 and an active region 103 may be formed in the substrate 101. A plurality of active regions 103 may be defined by the isolation layer 102. The substrate 101 may be a material appropriate for semiconductor processing. The substrate 101 may include a semiconductor substrate. The substrate 101 may be formed of a material containing silicon. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may also include other semiconductor materials, such as germanium. The substrate 101 may also include a III/V-group semiconductor substrate, for example, a compound semiconductor substrate, such as gallium arsenide (GaAs). The substrate 101 may also include a SOI (Silicon-On-Insulator) substrate. The isolation layer 102 may be formed by a Shallow Trench Isolation (STI) process.

A gate trench 105 may be formed in the substrate 101. A buried word line structure BWL may be formed in the gate trench 105. The buried word line structure BWL may include a gate dielectric layer 106, a buried word line 107, and a gate capping layer 108. The gate dielectric layer 106 may be formed on the surface of the gate trench 105. A buried word line 107 may be formed over the gate dielectric layer 106 to partially fill the gate trench 105. A gate capping layer 108 may be formed over the buried word line 107. The upper surface of the buried word line 107 may be disposed at a lower level than the surface of the substrate 101. The buried word line 107 may be a low-resistance metal material. The buried word line 107 may be formed by sequentially stacking titanium nitride and tungsten. According to another embodiment of the present disclosure, the buried word line 107 may be formed of titanium nitride only (TiN Only). The buried word line 106 may be referred to as a ‘buried gate electrode’. The buried word line 107 may extend in a first direction D1.

First and second impurity regions 109 and 110 may be formed in the substrate 101. The first and second impurity regions 109 and 110 may be spaced apart from each other by the gate trench 105. The first and second impurity regions 109 and 110 may be referred to as source/drain regions. The first and second impurity regions 109 and 110 may include an N-type impurity, such as arsenic (As) or phosphorus (P). The buried word line 107 and the first and second impurity regions 109 and 110 may be a cell transistor. The cell transistor may improve a short channel effect due to the buried word line 107.

The bit line contact plug 112 may be formed over the substrate 101. The bit line contact plug 112 may be coupled to the first impurity region 109. The bit line contact plug 112 may be disposed in a bit line contact hole 111. The bit line contact hole 111 may extend to the substrate 101 through a hard mask layer 104. The hard mask layer 104 may be formed over the substrate 101. The hard mask layer 104 may include a dielectric material. The bit line contact hole 111 may expose the first impurity region 109. The lower surface of the bit line contact plug 112 may be lower than the upper surfaces of the isolation layer 102 and the active region 103. The bit line contact plug 112 may be formed of polysilicon or a metal material. A portion of the bit line contact plug 112 may have a line width which is less than the diameter of the bit line contact hole 111. A stack of a bit line barrier 113A and the bit line 113 may be formed over the bit line contact plug 112, and a bit line hard mask 114 may be formed over the bit line 113. A stacked structure of the bit line contact plug 112, the bit line barrier 113A, the bit line 113, and the bit line hard mask 114 may be referred to as a bit line structure BL. The bit line 113 may have a line shape extending in a second direction D2 that intersects with the buried word line 107. A portion of the bit line barrier 113A may be coupled to the bit line contact plug 112. The bit line 113 and the bit line contact plug 112 may have the same line width in the first direction D1. Accordingly, the bit line 113 and the bit line barrier 113A may extend in the second direction D2 while covering the bit line contact plug 112. The bit line 113 may include a metal material, such as tungsten. The bit line hard mask 114 may include a dielectric material, such as silicon nitride.

A spacer structure 115 may be formed on a sidewall of the bit line structure BL. The spacer structure 115 may extend to be disposed on the sidewall of the bit line contact plug 112. The spacer structure 115 may include silicon nitride, silicon oxide, a low-k material, or a combination thereof. The low-k material may include SiBN, SiCO, SiCN, SiBCN, or a combination thereof. According to another embodiment of the present disclosure, the spacer structure 115 may include a multi-layer spacer. For example, it may include KK, KO, KN, NK, OK, KA, NKON, NKNAN, NKOK, NKOKN, NKAKN, KOK or KAK, where N refers to silicon nitride; K refers to a low-k material; O refers to silicon oxide; and A refers to an air gap. According to another embodiment of the present disclosure, the outermost spacer of the spacer structure 115 may include a low-k material. According to an embodiment of the present disclosure, the spacer structure 115 may include an inner spacer 115A and an outer spacer 115B. The inner spacer 115A may include silicon nitride, and the outer spacer 115B may include a low-k material.

A storage contact plug 116 may be formed between the neighboring bit line structures BL. The storage contact plug 116 may be coupled to the second impurity region 110. The storage contact plug 116 may include polysilicon, a metal nitride, a metal material, a metal silicide, or a combination thereof. According to some embodiments of the present disclosure, the storage contact plug 116 may include polysilicon, cobalt silicide, and tungsten that are stacked in the mentioned order.

From the perspective of a direction parallel to the bit line structure BL, a plug isolation structure 117 may be formed between the neighboring storage contact plugs 116. The plug isolation structure 117 may be formed between the neighboring bit line structures BL. The neighboring storage contact plugs 116 may be separated in the second direction D2 by the plug isolation structures 117. Between the neighboring bit line structures BL, a plurality of plug isolation structures 117 and a plurality of storage contact plugs 116 may be alternately disposed in the second direction D2. The storage contact plugs 116 may directly contact the spacer structures 115.

A memory element 130 may be formed over the storage contact plugs 116. The memory element 130 may include a capacitor including a storage node. The storage node may include a pillar type. Although not illustrated, a dielectric layer and a plate node may be further formed over the storage node. Other than the pillar type, the storage node may also have a cylindrical shape.

The plug isolation structure 117 may be referred to as an isolation layer or a pattern isolation layer. The plug isolation structure 117 may include an air gap, silicon nitride, a low-k material, or a combination thereof. When the plug isolation structure 117 includes a low-k material, the parasitic capacitance between the neighboring storage contact plugs 116 with the plug isolation structure 117 interposed therebetween may be decreased. The plug isolation structure 117 may include an air gap, SiCO, SiCN, SiOCN, SiBN, SiBCN, or a combination thereof.

Referring to FIGS. 1A to 1D, the semiconductor device 100 may include the bit line contact plug 112. The sidewall of the bit line contact plug 112 may include a multi-tapered profile. The sidewall of the bit line contact plug 112 may include a first tapered sidewall TS1, a second tapered sidewall TS2, and a vertical sidewall VS.

The bit line contact plug 112 may include a bottom portion 112L, a middle portion 112M, and a top portion 112U. The sidewall of the bottom portion 112L may include the first tapered sidewall TS1. The sidewall of the middle portion 112M may include the second tapered sidewall TS2. The sidewall of the top portion 112U may include the vertical sidewall VS. The slope of the vertical sidewall VS may be approximately 90°. The first tapered sidewall TS1 may have a first slope θ1 with respect to the bottom surface LV1 of the bottom portion 112L. The second tapered sidewall TS2 may have a second slope θ2 with respect to the bottom surface LV1 of the bottom portion 112L. The first slope θ1 of the first tapered sidewall TS1 and the second slope θ2 of the second tapered sidewall TS2 may be different from each other. The second slope θ2 of the second tapered sidewall TS2 may be closer to approximately 90° than the first slope θ1 of the first tapered sidewall TS1. Gap-fill layers G1 and G2 may be disposed in the peripheral area of the bottom portion 112L.

According to another embodiment of the present disclosure, the bit line contact plug 112 may include a lower buried portion that is coupled to the first impurity region 109 of the active region 13 and an upper buried portion whose width is less than the width of the lower buried portion. For example, the lower buried portion refers to the bottom portion 112L, and the upper buried portion refers to the middle portion 112M and the top portion 112U. According to another embodiment of the present disclosure, the lower buried portion refers to the bottom portion 112L and the middle portion 112M, whereas the upper buried portion refers to the top portion 112U.

The sidewall of the bit line contact plug 112 may include a plurality of inflection points, e.g., AG1 and AG2 at which the slope changes. For example, the inflection points AG1 and AG2 may include a first inflection point AG1 between the first tapered sidewall TS1 and the second tapered sidewall TS2, and a second inflection point AG2 between the second tapered sidewall TS2 and the vertical sidewall VS. The first and second inflection points AG1 and AG2 may be disposed at a higher level than the bottom surface LV2 of the storage contact plug 116. Also, the first and second inflection points AG1 and AG2 may be disposed at a higher level than the upper surfaces of the gap-fill layers G1 and G2.

The first tapered sidewall TS1 and the second tapered sidewall TS2 may have a tapered shape, and the vertical sidewall VS may have a vertical shape. The first tapered sidewall TS1 and the second tapered sidewall TS2 may provide a stepwise tapered shape. The gap-fill layers G1 and G2 may be disposed in the peripheral area of the bottom portion 112L. The space S1 between the middle portion 112M and the storage contact plug 116 may be secured sufficiently wide due to the multi-tapered profile. The multi-tapered profile may be secured with a wider space than the space S2 that may be obtained due to the single-tapered profile (see a reference symbol ‘TS’).

According to the above-described embodiment of the present disclosure, since the space S1 between the bit line contact plug 112 and the storage contact plug 116 is sufficient, current leakage may be prevented.

As the line width of the middle portion 112M of the bit line contact plug 112 decreases, the contact resistance may increase. However, since the line width of the bottom portion 112L is increased to secure sufficient volume, the increase in the contact resistance may be compensated for.

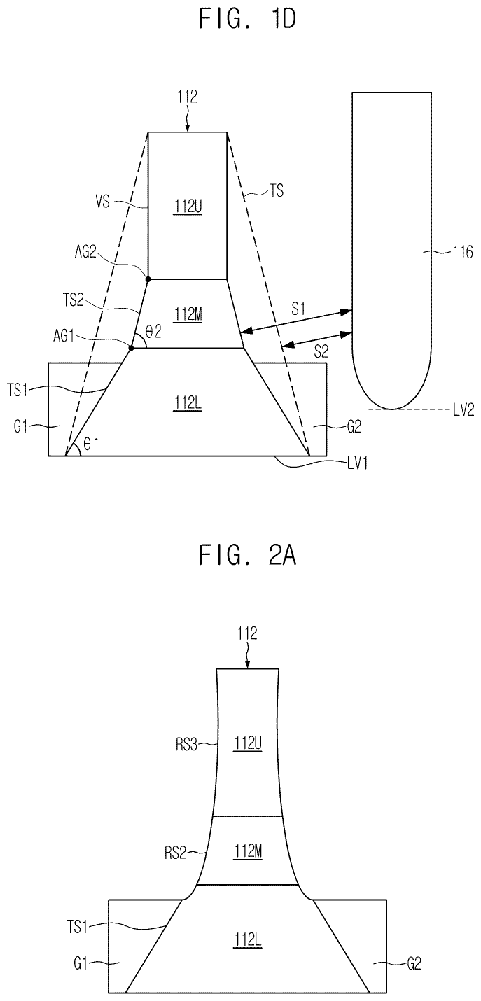

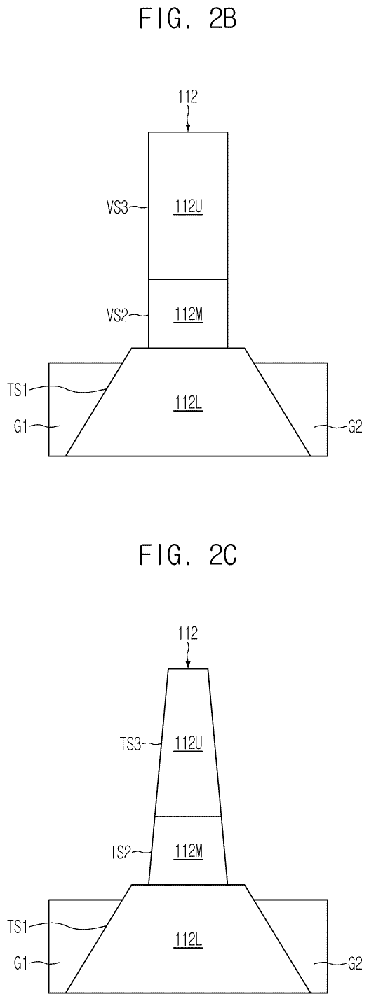

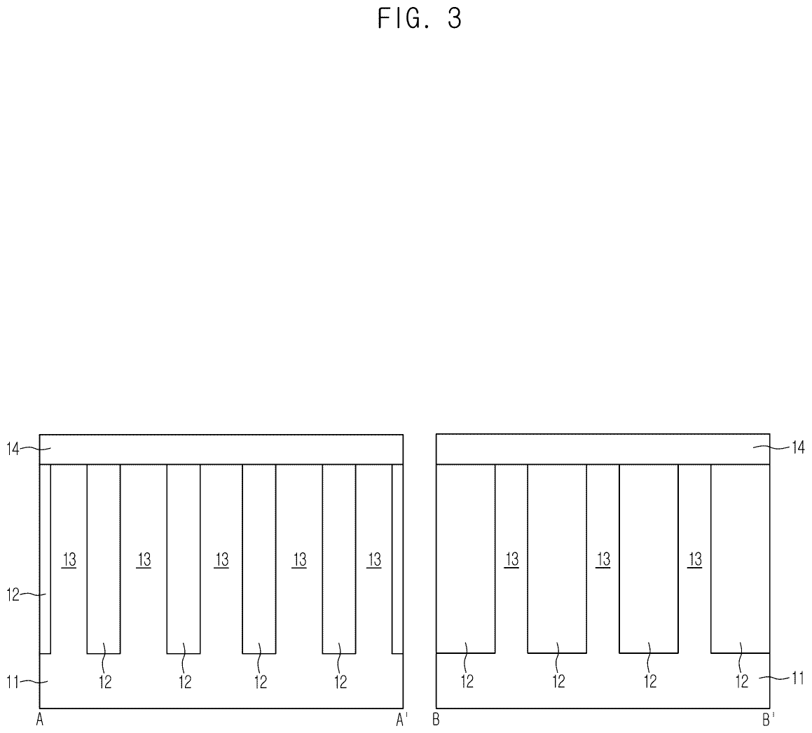

FIGS. 2A to 2C are cross-sectional views illustrating bit line contact plugs in accordance with other embodiments of the present disclosure.

Referring to FIG. 2A, the bit line contact plug 112 may include a bottom portion 112L, a middle portion 112M, and a top portion 112U. The sidewall TS1 of the bottom portion 112L may have a tapered shape, and the sidewall RS2 of the middle portion 112M and the sidewall RS3 of the top portion 112U may have round shapes. The sidewall TS1 of the bottom portion 112L and the sidewall RS2 of the middle portion 112M may provide a stepwise tapered shape. Gap-fill layers G1 and G2 may be disposed in the peripheral area of the bottom portion 112L.

Referring to FIG. 2B, the bit line contact plug 112 may include the bottom portion 112L, the middle portion 112M, and the top portion 112U. The sidewall TS1 of the bottom portion 112L may have a tapered shape, and the sidewall VS2 of the middle portion 112M and the sidewall VS3 of the top portion 112U may have vertical shapes. The sidewall TS1 of the bottom portion 112L and the sidewall VS2 of the middle portion 112M may provide a stepwise tapered shape. The gap-fill layers G1 and G2 may be disposed in the peripheral area of the bottom portion 112L.

Referring to FIG. 2C, the bit line contact plug 112 may include the bottom portion 112L, the middle portion 112M, and the top portion 112U. The sidewall TS1 of the bottom portion 112L may have a tapered shape, and the sidewall TS2 of the middle portion 112M and the sidewall TS3 of the top portion 112U may also have tapered shapes. The sidewall TS1 of the bottom portion 112L and the sidewall TS2 of the middle portion 112M may provide a stepwise tapered shape. The gap-fill layers G1 and G2 may be disposed in the peripheral area of the bottom portion 112L. The sidewalls of the middle and the top portions TS2 and TS3 may form a smooth continuous inclined surface.

FIGS. 3 to 15 are cross-sectional views illustrating a method for fabricating a semiconductor device in accordance with embodiments of the present disclosure. FIGS. 3 to 15 are cross-sectional views illustrating the fabrication method according to the lines A-A′ and B-B′ shown in FIG. 1A.

Referring to FIG. 3, an isolation layer 12 may be formed over a substrate 11. The isolation layer 12 may define a plurality of active regions 13 in the substrate 11. The isolation layer 12 may be formed by a Shallow Trench Isolation (STI) process. The STI process may be performed as follows. The substrate 11 may be etched to form an isolation trench (whose reference number is omitted). The isolation trench may be filled with a dielectric material, thereby forming the isolation layer 12. The isolation layer 12 may include silicon oxide, silicon nitride, or a combination thereof. Chemical Vapor Deposition (CVD) or other deposition processes may be used to fill the isolation trench with the dielectric material. A planarization process, such as Chemical-Mechanical Polishing (CMP), may additionally be used.

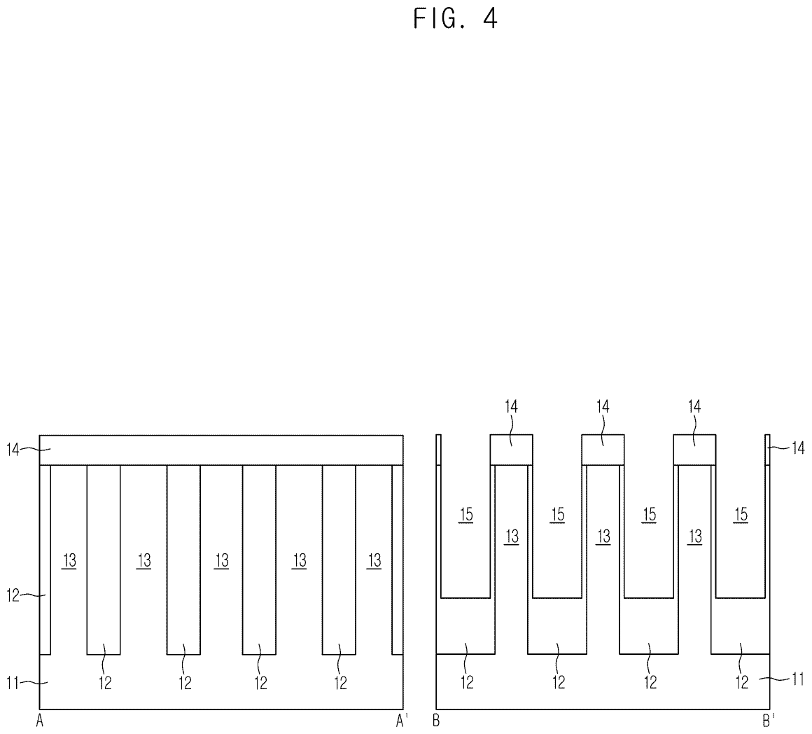

Referring to FIG. 4, a gate trench 15 may be formed in the substrate 11. The gate trench 15 may have a line shape crossing the active regions 13 and the isolation layer 12. The gate trench 15 may be formed by forming a mask pattern (not shown) over the substrate 11 and performing an etching process using the mask pattern as an etching mask. To form the gate trench 15, a hard mask layer 14 may be used as an etching barrier. The hard mask layer 14 may have a shape that is patterned by the mask pattern. The hard mask layer 14 may include silicon oxide. The hard mask layer 14 may include TEOS (Tetra Ethyl Ortho Silicate). The bottom surface of the gate trench 15 may be disposed at a higher level than the bottom surface of the isolation layer 12.

Although not illustrated, a portion of the isolation layer 12 may be recessed such that the active region 13 below the gate trench 15 may protrude. For example, the isolation layer 12 below the gate trench 15 may be selectively recessed in the longitudinal direction of the gate trench 15. Accordingly, a fin region (whose reference number is omitted) may be formed below the gate trench 15. The fin region may be a portion of a channel region.

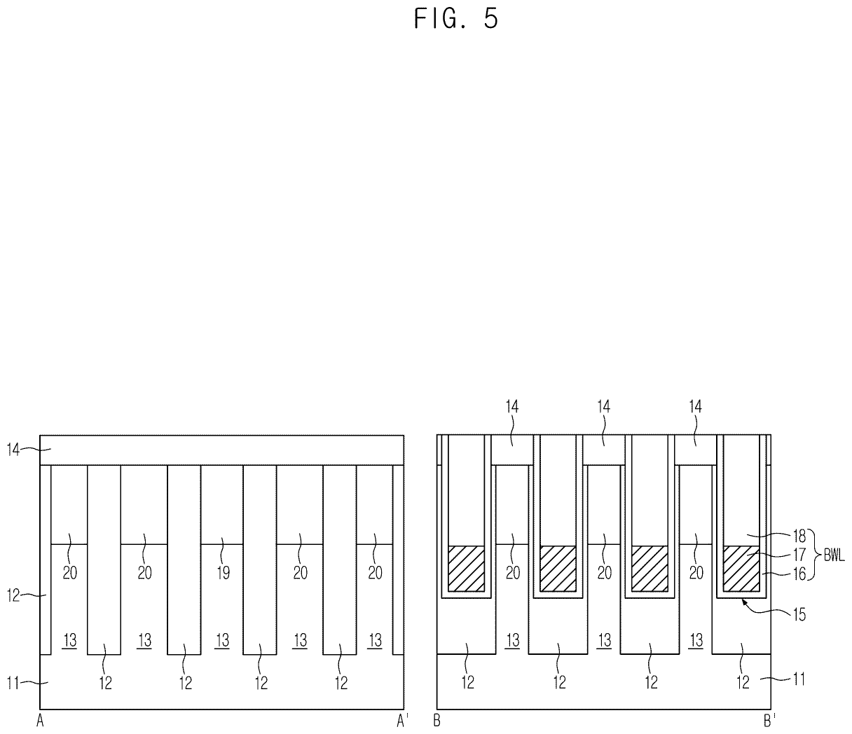

Referring to FIG. 5, a buried word line structure BWL may be formed in the gate trench 15. The buried word line structure BWL may include a gate dielectric layer 16 conformally covering the bottom surface and sidewall of the gate trench 15, a buried word line 17 partially filling a lower part of the gate trench 15 over the gate dielectric layer 16, and a gate capping layer 18 formed over the buried word line 17 to fill a remaining upper part of the gate trench 15.

A method of forming the buried word line structure BWL may be as follows. First, a gate dielectric layer 16 may be formed on the bottom surface and sidewalls of the gate trench 15. Before the gate dielectric layer 16 is formed, etching damage on the surface of the gate trench 15 may be repaired by curing. The curing process may involve, for example, forming a sacrificial oxide using by a thermal oxidation process, and then the sacrificial oxide may be removed. Forming the sacrificial oxide may involve exposing the silicon surface to an oxidizing environment (typically at high temperatures) to grow a thin layer of silicon dioxide (SiO₂) on the trench surface. This sacrificial oxide layer helps to repair the surface by consuming and passivating the defects. Once the sacrificial oxide layer has been formed and the surface damage is cured, the sacrificial oxide layer itself is removed. This may be done using a chemical etching process that selectively removes the oxide without harming the underlying silicon. The result is a smoother, defect-free silicon surface ready for the next step. The gate dielectric layer 16 may be formed by a thermal oxidation process. For example, the gate dielectric layer 16 may be formed by oxidizing the bottom and sidewall of the gate trench 15.

According to another embodiment of the present disclosure, the gate dielectric layer 16 may be formed by a deposition method such as Chemical Vapor Deposition (CVD) or Atomic Layer Deposition (ALD). The gate dielectric layer 16 may include a high-k material, an oxide, a nitride, an oxynitride, or a combination thereof. The high-k material may include a hafnium-containing material. The hafnium-containing material may include hafnium oxide, hafnium silicon oxide, hafnium silicon oxynitride, or a combination thereof. According to another embodiment of the present disclosure, the high-k material may include lanthanum oxide, lanthanum aluminum oxide, zirconium oxide, zirconium silicon oxide, zirconium silicon oxynitride, aluminum oxide, or a combination thereof.

According to another embodiment of the present disclosure, the gate dielectric layer 16 may be formed by depositing a liner polysilicon layer and then radically oxidizing the liner polysilicon layer.

According to yet another embodiment of the present disclosure, the gate dielectric layer 16 may be formed by forming a liner silicon nitride layer and then radically oxidizing the liner silicon nitride layer.

Subsequently, the buried word line 17 may be formed over the gate dielectric layer 16. The buried word line 17 may be formed by forming a conductive layer (not shown) to fill the gate trench 15, and then performing a recessing process. The conductive material may be deposited to fill the gate trench 15 using any suitable deposition process, including, for example, chemical vapor deposition (CVD), physical vapor deposition (PVD), and atomic layer deposition (ALD). The recessing process may be performed by an etch-back process, or by sequentially performing a Chemical-Mechanical Polishing (CMP) process and an etch-back process. The buried word line 17 may have a recessed shape that partially fills the gate trench 15. The upper surface of the buried word line 17 may be disposed at a lower level than the upper surface of the active region 13. The buried word line 17 may include a semiconductor material, a metal, a metal nitride, or a combination thereof. For example, the buried word line 17 may be formed of titanium nitride (TiN), tungsten (W), or a titanium nitride/tungsten (TiN/W) stack. The titanium nitride/tungsten (TiN/W) stack may have a structure that is formed by conformally forming titanium nitride and then partially filling the gate trench 15 with tungsten. Titanium nitride may be used alone as the buried word line 17, which may be referred to as a buried word line 17 of a ‘TiN Only’ structure. A double gate structure of a titanium nitride/tungsten (TiN/W) stack and a polysilicon layer may also be used as the buried word line 17.

Subsequently, a gate capping layer 18 may be formed over the buried word line 17. The gate capping layer 18 may include a dielectric material. The remaining portion of the gate trench 15 over the buried word line 17 may be filled with the gate capping layer 18 by depositing the dielectric material using a suitable deposition process such as chemical vapor deposition (CVD), physical vapor deposition (PVD), and atomic layer deposition (ALD). In an embodiment, the gate capping layer 18 may include silicon nitride. According to another embodiment of the present disclosure, the gate capping layer 18 may include silicon oxide. According to yet another embodiment of the present disclosure, the gate capping layer 18 may have a NON (Nitride-Oxide-Nitride) structure. The upper surface of the gate capping layer 18 may be disposed at the same level as the upper surface of the hard mask layer 14. To this end, a Chemical-Mechanical Polishing (CMP) process may be performed when the gate capping layer 18 is formed.

After the gate capping layer 18 is formed, impurity regions 19 and 20 may be formed. The impurity regions 19 and 20 may be formed by a doping process, such as an implantation process. The impurity regions 19 and 20 may include a first impurity region 19 and a second impurity region 20. The first and second impurity regions 19 and 20 may be doped with the impurities of the same conductivity type. The first and second impurity regions 19 and 20 may have the same depth. According to another embodiment of the present disclosure, the first impurity region 19 may be deeper than the second impurity region 20. The first and second impurity regions 19 and 20 may be referred to as source/drain regions. The first impurity region 19 may be a region to which the bit line contact plug is to be coupled, and the second impurity region 20 may be a region to which the storage contact plug is to be coupled. The first impurity region 19 and the second impurity region 20 may be disposed in different active regions 13. Also, the first impurity region 19 and the second impurity region 20 may be spaced apart from each other by the gate trenches 15 to be disposed in the respective active regions 13.

A cell transistor of a memory cell may be formed by the buried word line 17 and the first and second impurity regions 19 and 20.

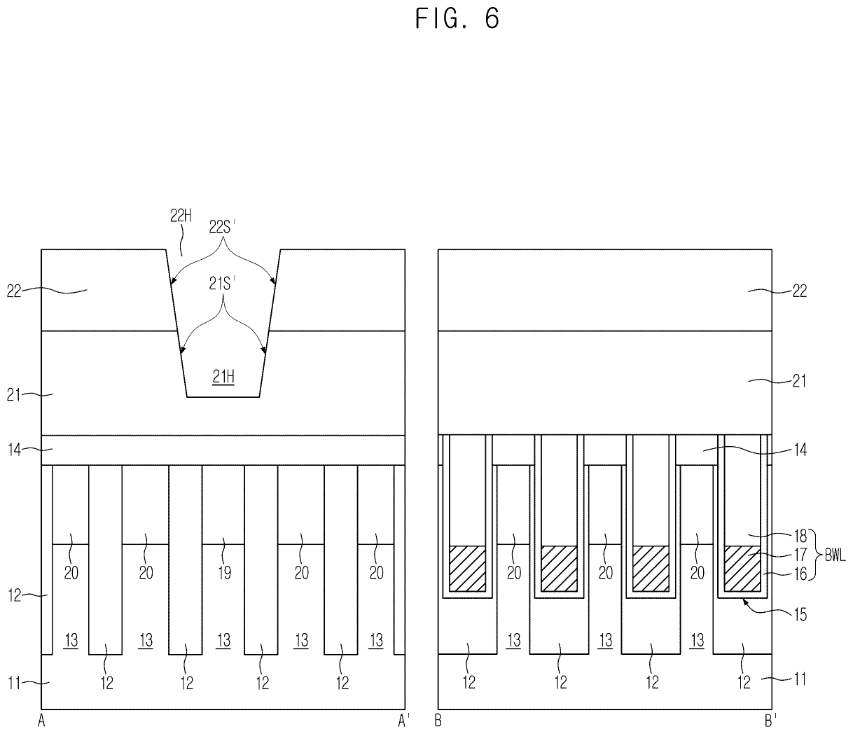

Referring to FIG. 6, a sacrificial hard mask layer 21 may be formed, e.g., by a deposition method, over the buried word line structure BWL and the hard mask layer 14. The sacrificial hard mask layer 21 may include silicon oxide, silicon nitride, or a combination thereof.

A mask pattern 22 may be formed over the sacrificial hard mask layer 21. The mask pattern 22 may include a material having an etching selectivity with respect to the sacrificial hard mask layer 21. The mask pattern 22 may include amorphous carbon, a photoresist, silicon oxide, silicon nitride, or a combination thereof. The mask pattern 22 may include a plurality of mask level openings 22H. From the perspective of a top view, the mask level openings 22H may have a hole shape. The sidewalls 22S′ of the mask level openings 22H may have a tapered shape or a slope shape.

Subsequently, a plurality of etching processes may be performed to form bit line contact holes.

First, a first etching process may be performed. The first etching process may etch a portion of the sacrificial hard mask layer 21 by using the mask pattern 22 as an etching barrier. The first etching process may be performed onto the sacrificial hard mask layer 21, and the first etching process may be a partial etching process that etches a portion of the sacrificial hard mask layer 21. Initial recessed openings 21H may be formed in a portion of the sacrificial hard mask layer 21 as a result of the first etching process. The initial recessed openings 21H may not pass through the sacrificial hard mask layer 21. From the perspective of a top view, the initial recessed openings 21H may have a hole shape. The initial recessed openings 21H may be formed along the profile of the mask level openings 22H. Accordingly, the sidewalls 21S′ of the initial recessed openings 21H may have a tapered shape or a slope shape.

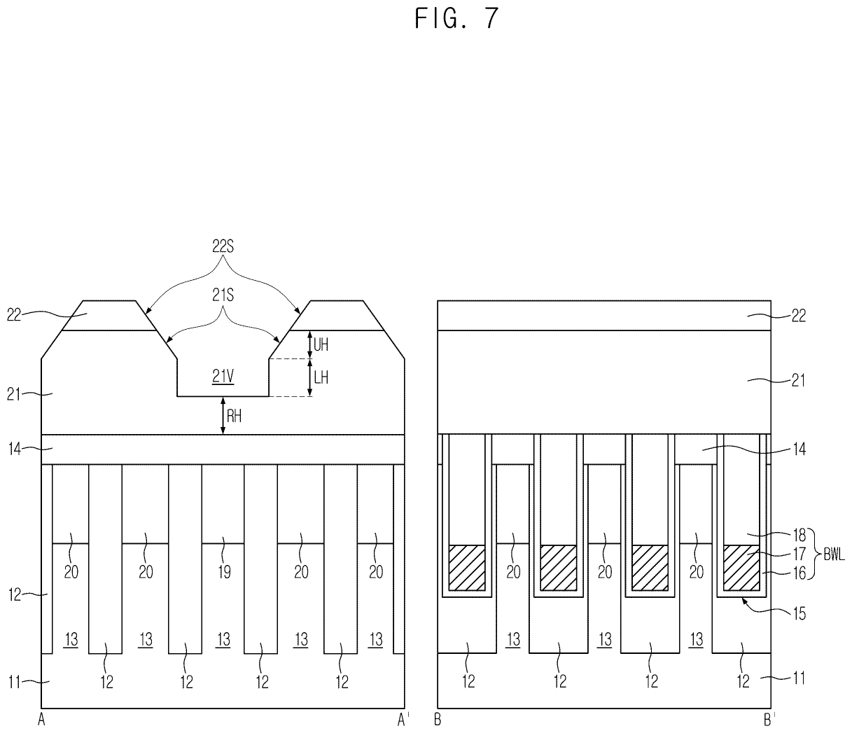

Referring to FIG. 7, a second etching process which involves isotropic etching may be performed. The second etching process may be performed onto the sacrificial hard mask layer 21, and the second etching process may be a partial etching process that etches a portion of the sacrificial hard mask layer 21. Recessed openings 21V may be formed in a portion of the sacrificial hard mask layer 21 by the second etching process. The recessed openings 21V may not pass through the sacrificial hard mask layer 21. From the perspective of a top view, the recessed openings 21V may have a hole shape. The recessed openings 21V may have a circular or oval cross-section. The recessed openings 21V may be formed along the profile of the mask level openings (22H of FIG. 6). Accordingly, the sidewalls 21S of the recessed openings 21V may have a tapered shape or a slope shape. During the second etching process or before the second etching process is performed, a portion of the mask pattern 22 may be etched. As a result, the height of the mask pattern 22 may be decreased, but the sidewalls 22S of the mask level openings 22H may have a tapered shape or a slope shape.

The recessed openings 21V may include a lower opening LH and an upper opening UH. The sidewall of the lower opening LH may have a vertical shape, and the sidewall of the upper opening UH may have a tapered shape or a slope shape. The lower opening LH and the upper opening UH may have the same height or different heights. The average diameter of the lower opening LH may be less than the average diameter of the upper opening UH. The shape of the recessed openings 21V may be referred to as a dish shape. The initial body RH of the sacrificial hard mask layer 21 may remain below the recessed openings 21V.

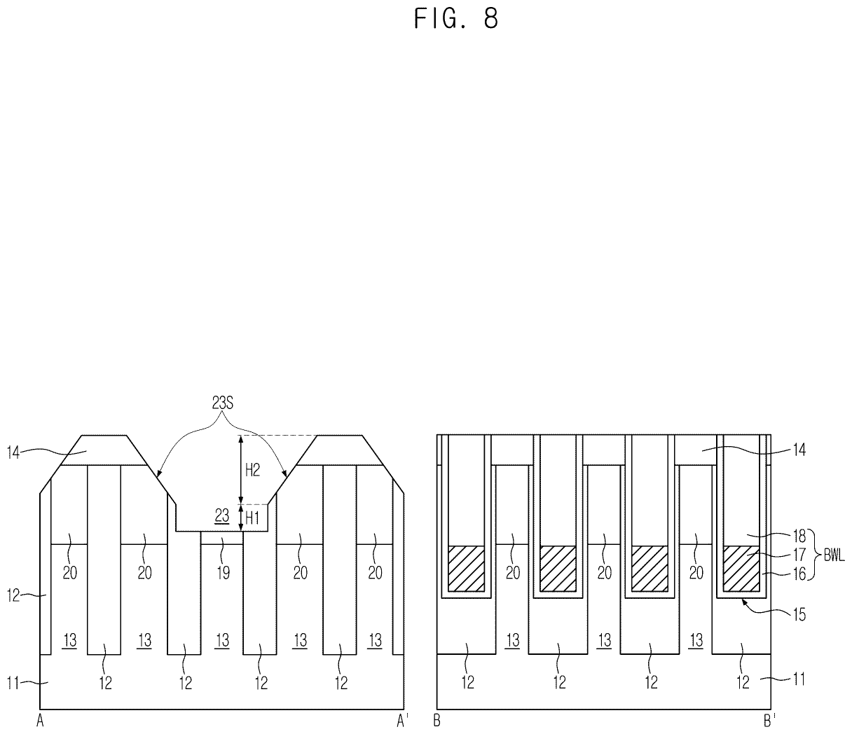

Referring to FIG. 8, a third etching process may be performed. A bit line contact hole 23 may be formed in the active region 13 by the third etching process. The third etching process for forming the bit line contact hole 23 may include sequentially etching the initial body RH of the sacrificial hard mask layer 21, the hard mask layer 14, and the isolation layer 12 by using the mask pattern 22 as an etching barrier, and etching a portion of the active region 13. After the process of etching the portion of the active region 13, the mask pattern 22 and the sacrificial hard mask layer 21 may be consumed and may not remain.

The initial body RH of the sacrificial hard mask layer 21, the hard mask layer 14, the isolation layer 12, and a portion of the active region 13 may be etched along the profile of the mask pattern 22 and the recessed openings 21V. To be specific, the profile of the recessed openings 21V may be transferred vertically downward to form the bit line contact hole 23.

A dish-shaped bit line contact hole 23 may be formed by the first to third etching processes as described above. From the perspective of a top view, the bit line contact hole 23 may be of a hole shape.

The bit line contact holes 23 may include a lower opening H1 and an upper opening H2. A sidewall of the lower opening H1 may have a vertical shape while a sidewall 23S of the upper opening H2 may have a tapered shape or a slope shape. The lower opening H1 may have a shorter height than the upper opening H2. The average diameter of the lower opening H1 may be less than the average diameter of the upper opening H2. The diameter of the upper opening H2 may be increasing as the distance from the first impurity region increases. The bit line contact holes 23 shape may be referred to as a dish shape. The first impurity region 19 may be disposed below the bit line contact hole 23. A portion of the first impurity region 19 may be recessed during the formation of the bit line contact hole 23. The upper portion of the upper opening H2 of the bit line contact holes 23 may be provided by the hard mask layer 14. The sidewall of the hard mask layer 14 may have a tapered shape or a slope shape.

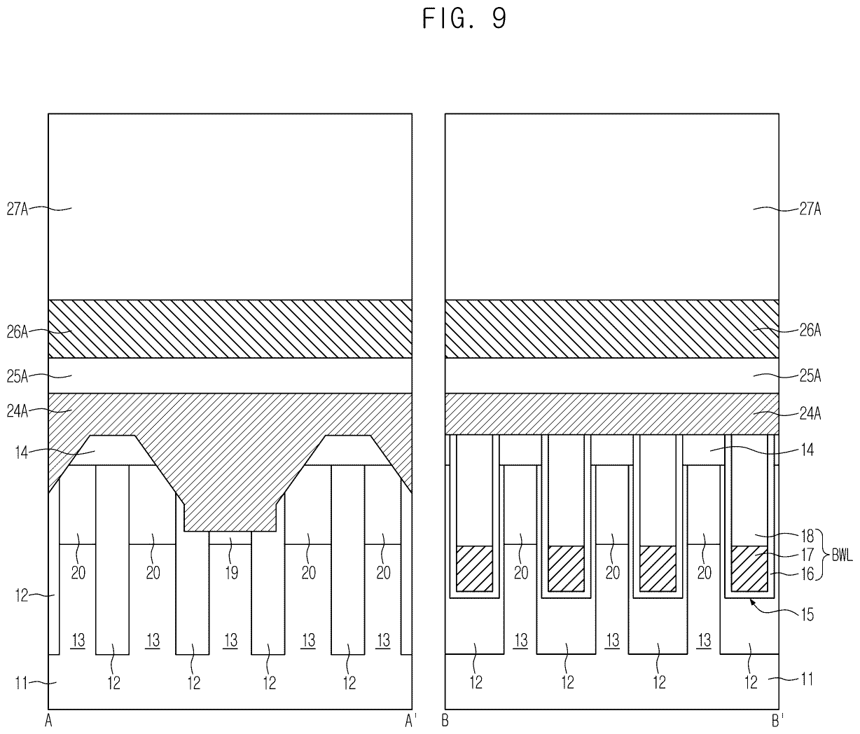

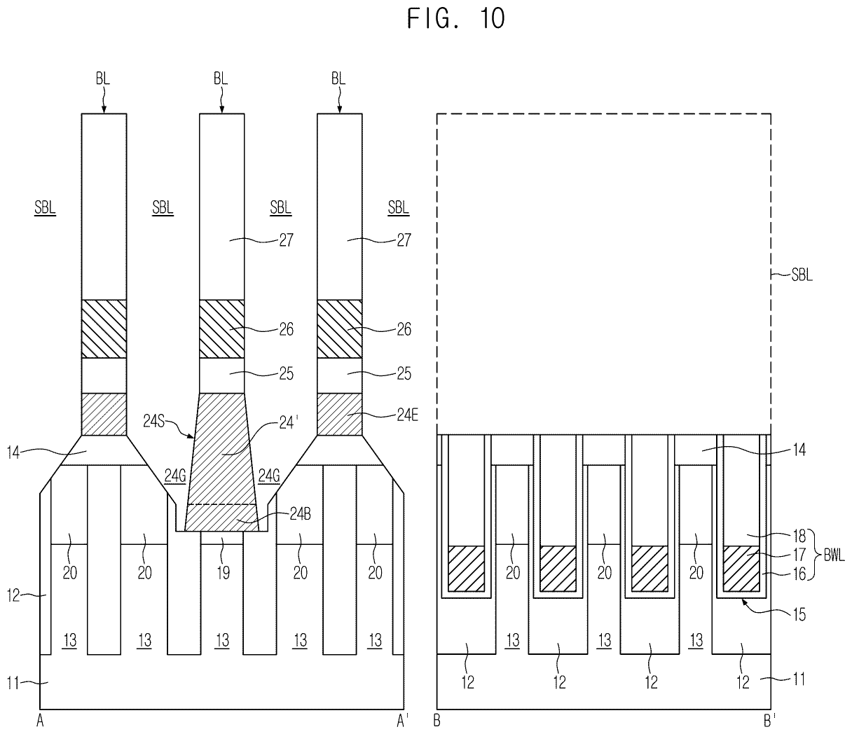

Referring to FIG. 9, a plug layer 24A may be formed in the bit line contact holes 23. The plug layer 24A may be formed over the hard mask layer 14 and the buried word line structure BWL while filling the bit line contact holes 23. The plug layer 24A may include a conductive material, for example, polysilicon or doped polysilicon.

A bit line barrier layer 25A, a bit line conductive layer 26A, and a bit line hard mask layer 27A may be sequentially formed over the plug layer 24A. The bit line barrier layer 25A and the bit line conductive layer 26A may include a metal-containing material. The bit line barrier layer 25A and the bit line conductive layer 26A may include a metal, a metal nitride, a metal silicide, or a combination thereof. According to an embodiment of the present disclosure, the bit line barrier layer 25A may include titanium nitride, and the bit line conductive layer 26A may include tungsten (W). The bit line hard mask layer 27A may include silicon oxide or silicon nitride. According to an embodiment of the present disclosure, the bit line hard mask layer 27A may be formed of silicon nitride.

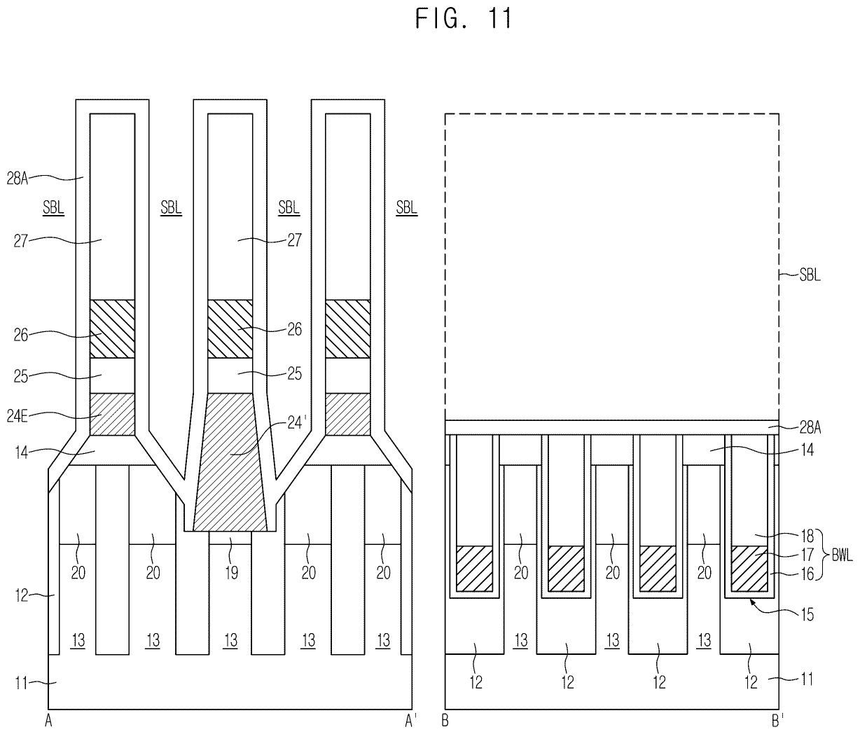

Referring to FIG. 10, a line structure including a first conductive pattern, i.e., a bit line structure BL, may be formed. The bit line structure BL may include a stack of a bit line contact plug 24′, a bit line barrier 25, a bit line 26, and a bit line hard mask 27. The bit line contact plug 24′, the bit line barrier 25, the bit line 26, and the bit line hard mask 27 may be formed by an etching process using a bit line mask layer (not illustrated). In the bit line structure BL, the first conductive pattern may include a bit line 26.

The bit line hard mask layer 27A, the bit line conductive layer 26A, and the bit line barrier layer 25A may be etched by using the bit line mask layer (not shown) as an etching barrier. Accordingly, the bit line barrier 25, the bit line 26, and the bit line hard mask 27 may be formed. The bit line hard mask 27 may be formed by etching the bit line hard mask layer 27A. The bit line 26 may be formed by etching the bit line conductive layer 26A. The bit line barrier 25 may be formed by etching the bit line barrier layer 25A.

Subsequently, the plug layer 24A below the bit line barrier 25 may be etched to form the bit line contact plug 24′. The bit line contact plug 24′ may be formed over the first impurity region 19. The bit line contact plug 24′ may interconnect the first impurity region 19 and the bit line barrier 25 to each other. The bit line contact plug 24′ may be formed in the bit line contact hole 23. The average diameter of the bit line contact plug 24′ may be less than the average diameter of the bit line contact hole 23. Therefore, a gap 24G may be defined in the peripheral area of the bit line contact plug 24′.

The bit line contact plug 24′ may include extended portions 24E, and the extended portions 24E of the bit line contact plug 24′ may be disposed in the upper portion of the hard mask layer 14. Accordingly, the bit line contact plug 24′ may extend in a direction that the bit line 26 extends while filling the bit line contact hole 23.

The sidewall 24S of the bit line contact plug 24′ may have a non-vertical shape. For example, the sidewall 24S of the bit line contact plug 24′ may have a tapered shape or a slope shape. The bit line contact plug 24′ may have different diameters according to the height direction. For example, the diameter of the bottom portion 24B of the bit line contact plug 24′ may be the largest, and the diameter may gradually decrease according to the height. The lower portion of the gap 24G may be disposed in the peripheral area of the bottom portion 24B of the bit line contact plug 24′. The lower portion of the gap 24G may extend to be disposed in the isolation layer 12.

Referring to FIGS. 8 to 10, the gap 24G may be formed in the bit line contact hole 23 by forming the bit line contact plug 24′. This is because the bit line contact plug 24′ is formed by being etched to be less than the diameter of the bit line contact hole 23. The gap 24G may be formed not in a surrounding shape that surrounds the bit line contact plug 24′, but may be formed independently on both sidewalls of the bit line contact plug 24′. As a result, one bit line contact plug 24′ and a pair of gaps 24G may be disposed in the bit line contact hole 23, and the pair of gaps 24G may be separated by the bit line contact plug 24′. The bottom surface of the gap 24G may extend into the inside of the isolation layer 12. The bottom surface of the gap 24G may be disposed at a lower level than the recessed upper surface of the first impurity region 19. According to another embodiment of the present disclosure, from the perspective of a top view, the gap 24G may have a surrounding shape that surrounds the bit line contact plug 24′.

A structure including the bit line contact plug 24′, the bit line barrier 25, the bit line 26, and the bit line hard mask 27 that are stacked in the mentioned order may be referred to as a bit line structure BL. From the perspective of a top view, the bit line structure BL may be a line-shaped pattern structure extending in the second direction D2.

A line-shaped opening SBL may be defined between the neighboring bit line structures BL. The line-shaped opening SBL may be parallel to the bit line structures BL. The upper surfaces of the hard mask layer 14 and the buried word line structure BWL may be exposed by the line-shaped opening SBL.

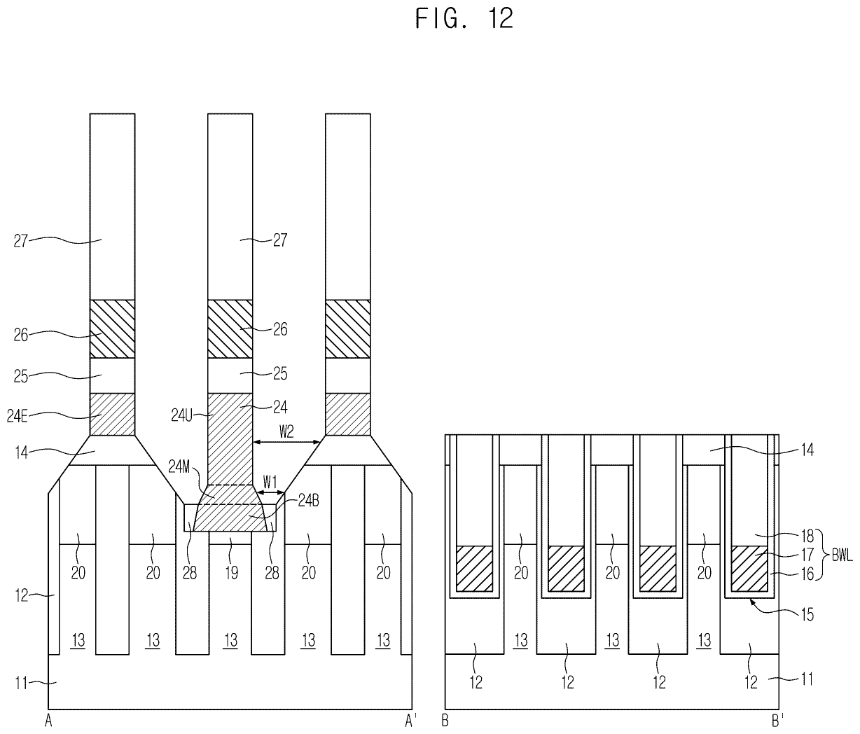

Referring to FIG. 11, a preliminary gap-fill layer 28A may be formed on both sidewalls of the bit line structure BL. The preliminary gap-fill layer 28A may be formed over the bit line structure BL while filling the gap 24G. The preliminary gap-fill layer 28A may include a dielectric material. The preliminary gap-fill layer 28A may include silicon nitride, silicon oxide, a low-k material, or a combination thereof. The low-k material may include SiBN, SiCO, SiCN, SiBCN, or a combination thereof. According to another embodiment of the present disclosure, the preliminary gap-fill layer 28A may include a multi-layer structure. For example, the preliminary gap-fill layer 28A may include NKON, NKNAN, NKOK, NKOKN, NKAKN, KOK or KAK, multi-layer structures, where N refers to silicon nitride; K refers to a low-k material; O refers to silicon oxide; and A refers to an air gap. According to another embodiment of the present disclosure, the outermost material of the preliminary gap-fill layer 28A may include a low-k material.

A portion of the preliminary gap-fill layer 28A may fill the bottom portion of the gap 24G, i.e., the peripheral area of the bottom portion 24B of the bit line contact plug 24′. A portion of the preliminary gap-fill layer 28A may cover the upper surfaces of the hard mask layer 14 and the buried word line structure BWL.

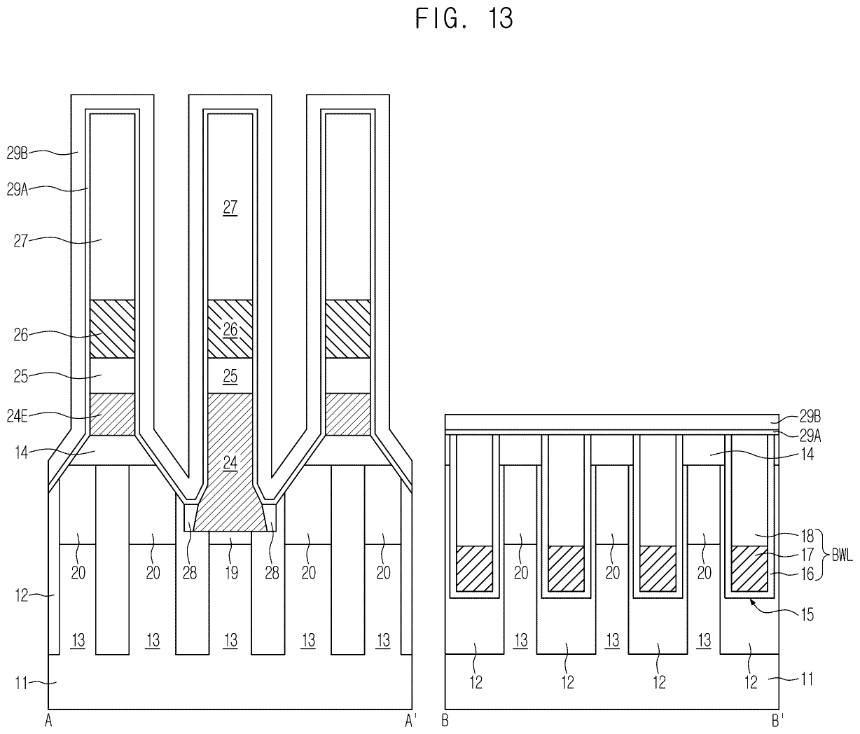

Referring to FIG. 12, the preliminary gap-fill layer 28A may be selectively recessed to form the gap-fill layer 28.

A side recess process of the bit line contact plug 24′ may be performed during or after the recess process for forming the gap-fill layer 28. As a result, the bit line contact plug 24 may be formed, and the sidewall of the bit line contact plug 24 may have a stepwise tapered shape.

The bit line contact plug 24 may include an extended portion 24E, a bottom portion 24B, a middle portion 24M, and a top portion 24U. The extended portion 24E refers to a portion of the top portion 24U. The bottom portion 24B and the middle portion 24M of the bit line contact plug 24 may include tapered sidewalls, and the top portion 24U of the bit line contact plug 24 may include a vertical sidewall. A stepwise tapered shape may be defined by the sidewall profiles of the bottom portion 24B, the middle portion 24M, and the top portion 24U. In the bit line contact plug 24, the height of the bottom portion 24B may be greater than the height of the middle portion 24M, and the height of the top portion 24U may be greater than the height of the bottom portion 24B.

As described above, during the recess process for forming the gap-fill layer 28, the sidewall of the bit line contact plug 24 may be side-recessed, thereby sufficiently securing the contact burying space W1 and W2.

The contact resistance may increase, as the line width of the middle portion 24M of the bit line contact plug 24 decreases. However, since the line width of the bottom portion 24B is increased so as to secure sufficient volume, the increase in the contact resistance may be compensated for. To be specific, as the necking linewidth of the middle portion 24M decreases during the side recess process, the contact resistance may increase. However, since the line width of the bottom portion 24B is increased to secure sufficient volume, the increase in the contact resistance may be compensated for.

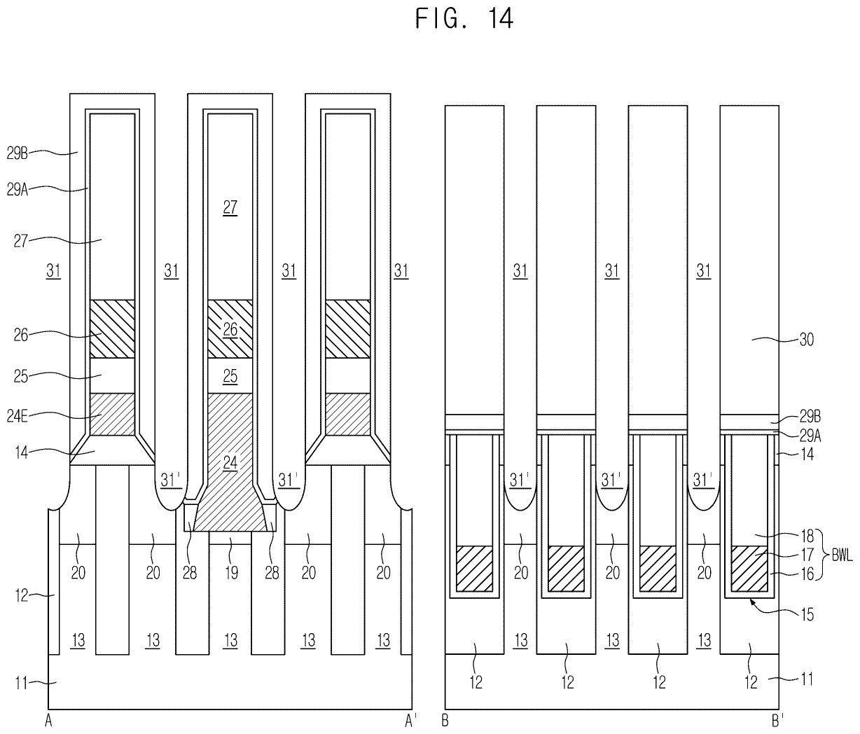

Referring to FIG. 13, a spacer structure may be formed conformally over the gap-fill layer 28 and the bit line structure BL. The spacer structure may be a double structure of a first spacer layer 29A and a second spacer layer 29B. The first spacer layer 29A may be formed over the gap-fill layer 28 and the bit line structure BL, and the second spacer layer 29B may be formed over the first spacer layer 29A. The first spacer layer 29A may be thinner than the second spacer layer 29B. The first and second spacer layers 29A and 29B may include a dielectric material. The first and second spacer layers 29A and 29B may include silicon nitride, silicon oxide, a low-k material, or a combination thereof. The low-k material of the first and second spacer layers 29A and 29B may include SiBN, SiCO, SiCN, SiBCN, or a combination thereof. The second spacer layer 29B may have a lower dielectric constant than the first spacer layer 29A. According to another embodiment of the present disclosure, a spacer structure having a multi-layer structure of three or more layers may be formed in addition to the double structure of the first and second spacer layers 29A and 29B. For example, the multi-layer spacer structure may include NKN, KNN, KON, NOK, NKON, NKNAN, NKOK, NKOKN, NKAKN, KOK or KAK, where N refers to silicon nitride; K refers to a low-k material; O refers to silicon oxide; and A refers to an air gap. According to another embodiment of the present disclosure, the outermost material in the multi-layer spacer structure may include a low-k material.

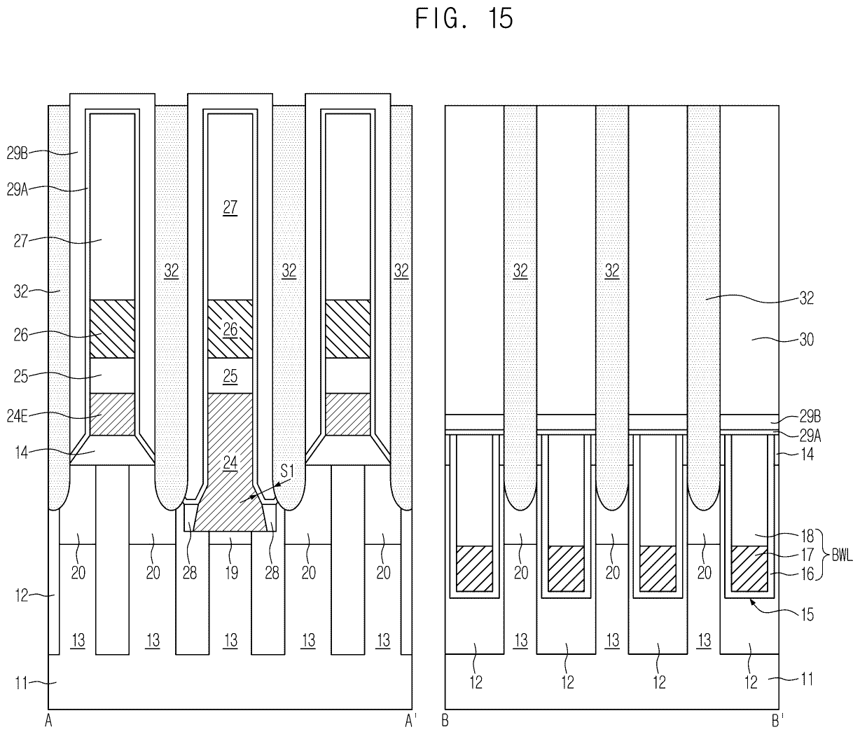

Referring to FIG. 14, plug isolation layers 30 may be formed between the bit line structures BL over the first and second spacer layers 29A and 29B. Forming the plug isolation layers 30 may include depositing and etching the plug isolation material to form a plurality of hole-shaped openings 31 between the plug isolation layers 30.

The plug isolation layers 30 may include silicon nitride, silicon oxide, a low-k material, or a combination thereof. The low-k material of the plug isolation layers 30 may include SiBN, SiCO, SiCN, SiBCN, or a combination thereof.

After the first and second spacer layers 29A and 29B are etched below the hole-shaped openings 31, the underlying materials may be etched to be self-aligned to the spacer layers 29A and 29B. Accordingly, a plurality of recess regions 31′ exposing a portion of the active region 13 between the bit line structures BL may be formed. Anisotropic etching or a combination of anisotropic etching and isotropic etching may be used to form the recess regions 31′. For example, anisotropic etching may be performed to form first and second spacer layers 29A and 29B between the bit line structures BL, and then a portion of the exposed active region 13 may be isotropically etched. According to another embodiment of the present disclosure, the hard mask layer 14 may also be isotropically etched. Portions of the active region 13, for example, second impurity regions 20, may be partially exposed by the recess regions 31′.

The recess regions 31′ may extend into the inside of the substrate 11. While the recess regions 31′ are formed, the isolation layer 12, the gate capping layer 18, and the second impurity region 20 may be recessed to a predetermined depth. The bottom surface of the recess regions 31′ may be disposed at a level which is lower than the upper surface of the bit line contact plug 24. The bottom surface of the recess regions 31′ may be disposed at a level which is higher than the bottom surface of the bit line contact plug 24. The hole-shaped openings 31 and the recess regions 31′ may be interconnected to each other. The vertical structure of the hole-shaped openings 31 and the recess regions 31′ may be referred to as a ‘storage contact hole’.

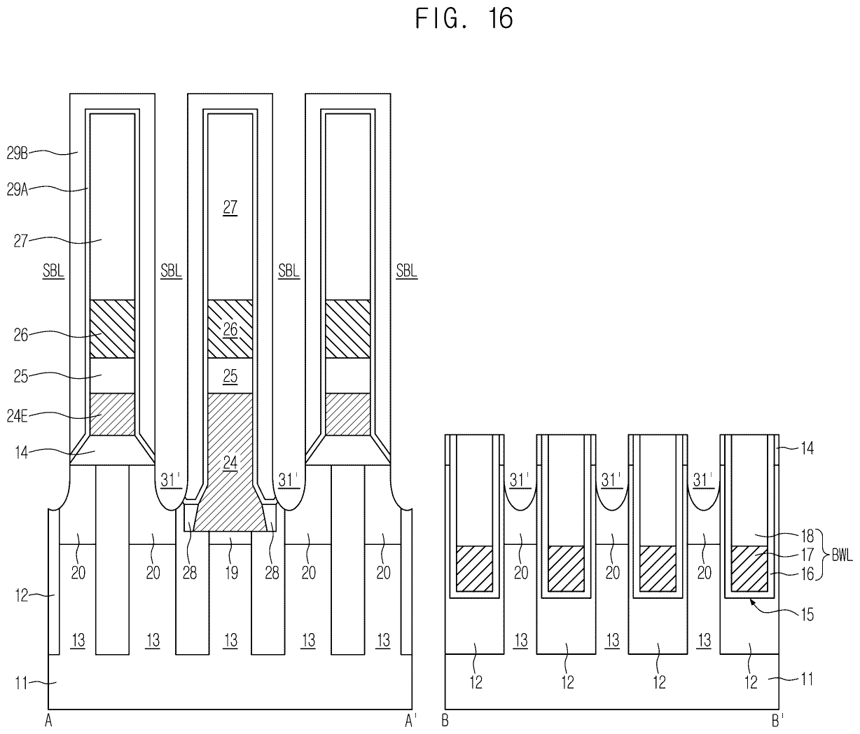

Referring to FIG. 15, storage contact plugs 32 may be formed to fill the hole-shaped openings 31 and the recessed region 31′. The storage contact plugs 32 may include a semiconductor material, for example, doped polysilicon. The storage contact plugs 32 may be formed by depositing the semiconductor material to fill the hole-shaped openings 31 and the recessed region 31′.

According to the above-described embodiment of the present disclosure, a sufficient space S1 is formed between the bit line contact plug 24 and the storage contact plug 32, and, as a result, current leakage may be prevented.

As the line width of the middle portion 24M of the bit line contact plug 24 decreases, the contact resistance may increase. However, since the line width of the bottom portion 24B is increased to secure a sufficient volume, the increase in contact resistance may be compensated for.

Since the bit line contact plug (24′ of FIG. 10) has a partial slope profile during the etching process for forming the bit line contact plug, the bottom space may be sufficiently secured during the subsequent side recess process (see FIG. 12).

Since the vertical height of the active region 13 where the storage contact plug 32 is to be landed is protected during the etching process, the vertical spacing distance between the storage contact plug 32 and the bit line contact plug 24 may be sufficiently secured.

The increase in the contact resistance that may be accompanied by the thinning of the line width of the bit line contact plug 24 may be compensated for by increasing the line width of the bottom portion to increase the volume.

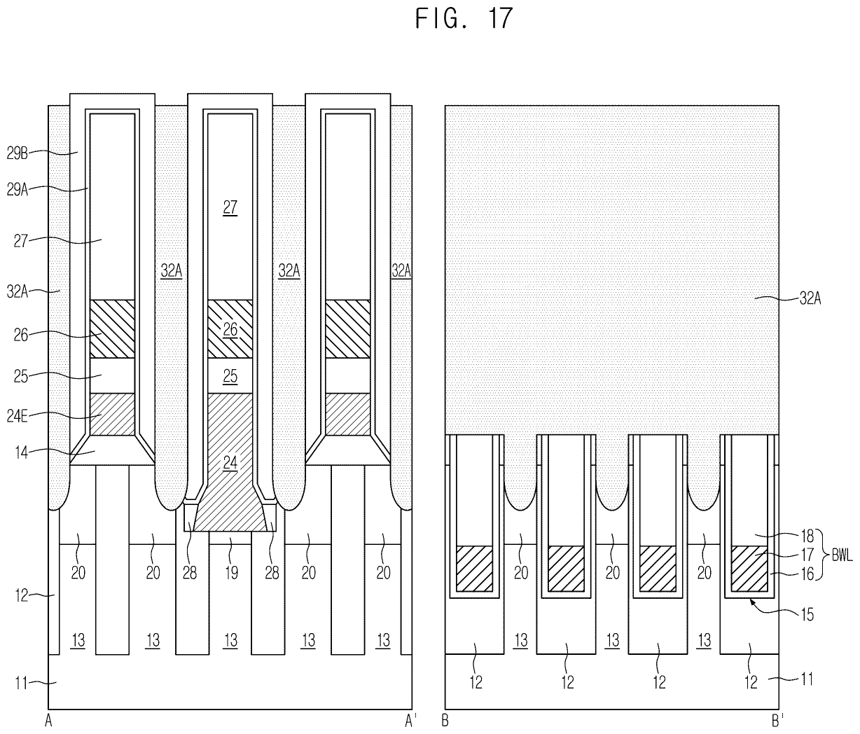

FIGS. 16 to 19 are cross-sectional views illustrating a method for fabricating a semiconductor device in accordance with another embodiment of the present disclosure.

First, by performing a series of processes illustrated in FIGS. 3 to 13, first and second spacer layers 29A and 29B may be formed over the bit line structure BL.

Referring to FIG. 16, after the first and second spacer layers 29A and 29B below the line-shaped openings SBL are etched, the underlying materials may be etched to be self-aligned to the first and second spacer layers 29A and 29B. As a result, a plurality of recess regions 31′ exposing a portion of the active region 13 between the bit line structures BL may be formed. Anisotropic etching or a combination of anisotropic etching and isotropic etching may be used to form the recess regions 31′. For example, anisotropic etching may be performed to form the first and second spacer layers 29A and 29B between the bit line structures BL, and then a portion of the exposed active region 13 may be isotropically etched. According to another embodiment of the present disclosure, the hard mask layer 14 may also be isotropically etched. Portions of the active region 13 may be exposed by the recess regions 31′.

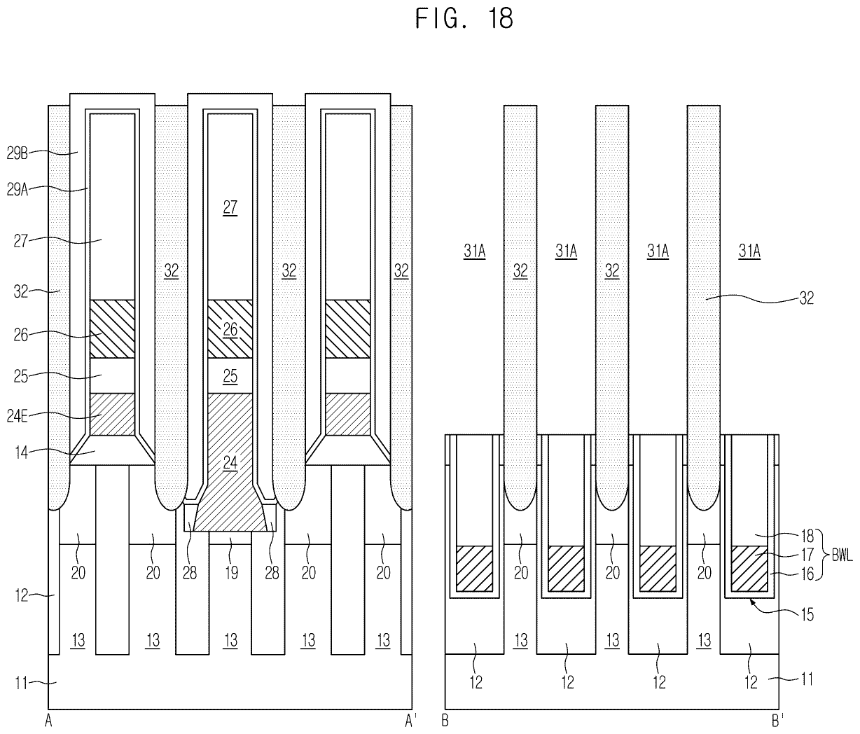

Referring to FIG. 17, line patterns 32A may be formed over the first and second spacer layers 29A and 29B to fill each of the line-shaped openings SBL between the bit line structures BL. The line patterns 32A may fill the line-shaped openings SBL and the recess regions 31′. The line patterns 32A may contact the second impurity regions 20. The line patterns 32A may be adjacent to the bit line structures BL. From the perspective of a top view, a plurality of line patterns 32A may be disposed between the bit line structures BL. The line patterns 32A may include a semiconductor material, for example, doped polysilicon.

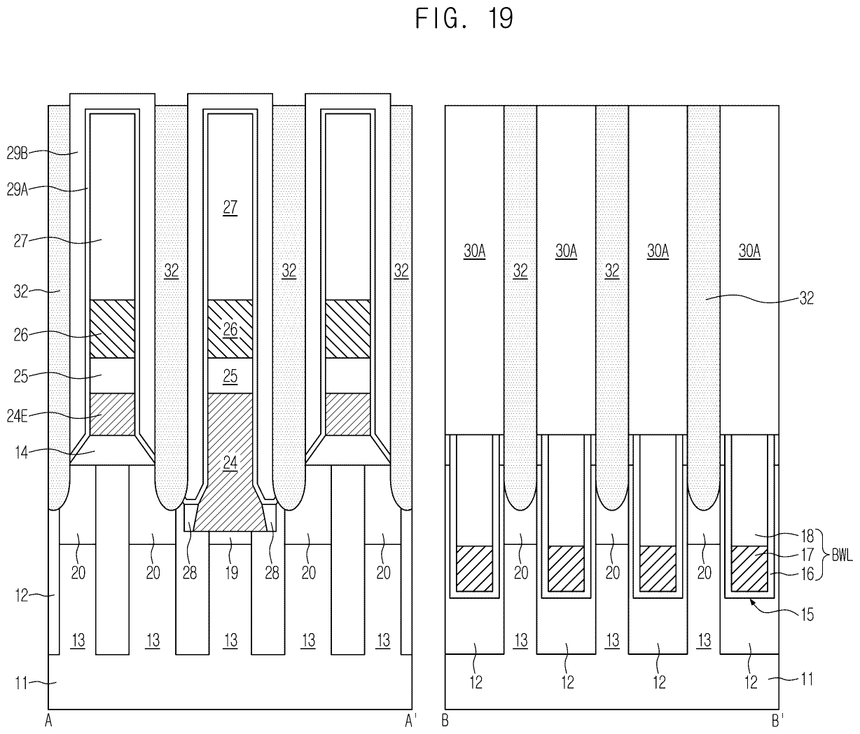

Referring to FIG. 18, the line patterns 32A may be etched using a mask layer extending in a direction that intersects with the line patterns 32A. Accordingly, a plurality of storage contact plugs 32 and a plurality of isolation holes 31A may be formed. From the perspective of a top view, a plurality of storage contact plugs 32 may be disposed between the neighboring bit line structures BL, and isolation holes 31A may be disposed between the storage contact plugs 32. The storage contact plugs 32A may be referred to as second conductive pattern structures.

Referring to FIG. 19, plug isolation layers 30A may be formed to fill the isolation holes 31A. Forming the plug isolation layers 30A may include depositing and etching a plug isolation material. A plurality of storage contact plugs 32 may be formed between the plug isolation layers 30A.

The plug isolation layers 30A may include silicon nitride, silicon oxide, a low-k material, or a combination thereof. The low-k material of the plug isolation layers 30A may include SiBN, SiCO, SiCN, SiBCN, or a combination thereof.

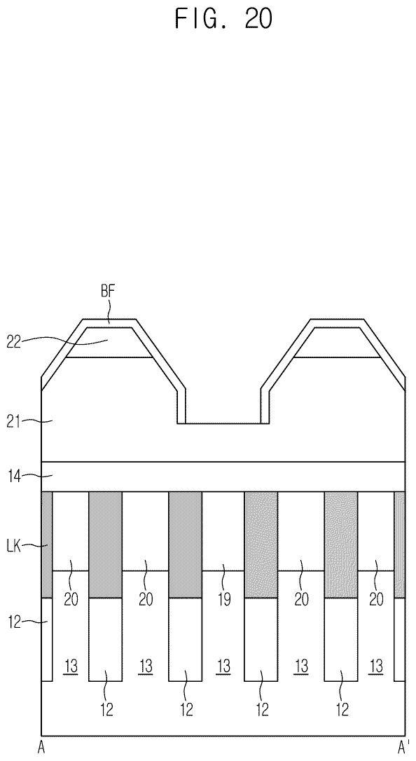

FIGS. 20 to 23 are cross-sectional views illustrating a method for fabricating a semiconductor device in accordance with another embodiment of the present disclosure. FIGS. 20 to 23 are cross-sectional views illustrating the fabrication method according to the line A-A′ shown in FIG. 1A.

First, a series of processes as illustrated in FIGS. 3 to 7, i.e., the first and second etching processes, may be performed. According to this embodiment of the present disclosure, a low-k stopper layer LK, such as SiOC, may be formed over the isolation layer 12. The low-k stopper layer LK may function to prevent electrical leakage in the peripheral area of the bit line contact plug.

Subsequently, referring to FIG. 20, a buffer spacer BF may be formed over the sacrificial hard mask layer 21 and the mask pattern 22. The buffer spacer BF may be formed by depositing and etching silicon nitride.

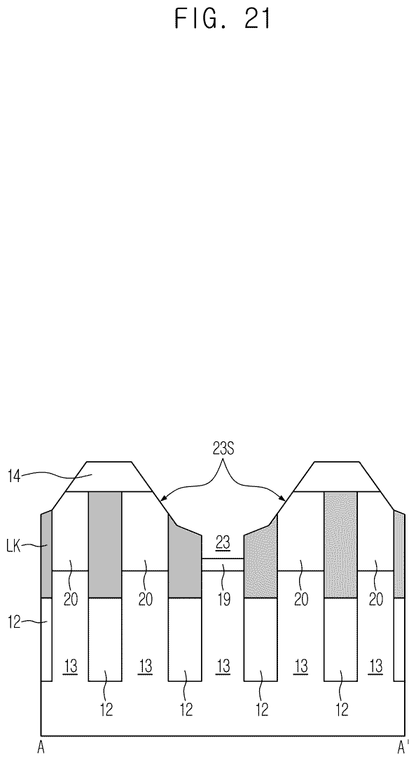

Referring to FIG. 21, a third etching process may be performed. A bit line contact hole 23 may be formed in the active region 13 by the third etching process. The third etching process for forming the bit line contact hole 23 may include sequentially etching the sacrificial hard mask layer 21, the hard mask layer 14, and the isolation layer 12 by using the mask pattern 22 and the buffer spacer BF as an etching barrier, and etching a portion of the active region 13. After the process of etching a portion of the active region 13, the mask pattern 22 and the sacrificial hard mask layer 21 may be consumed and may not remain.

The sacrificial hard mask layer 21, the hard mask layer 14, the isolation layer 12, and a portion of the active region 13 may be etched along the profile of the buffer spacer BF. Since the etching process is performed along the profile of the buffer spacer BF, a narrow bit line contact hole 23 may be formed.

A dish-shaped bit line contact hole 23 may be formed by the first to third etching processes as described above. From the perspective of a top view, the bit line contact hole 23 may be a hole shape.

Referring to FIGS. 8 and 21 together, the bit line contact holes 23 may include a lower opening H1 and an upper opening H2. The sidewall of the lower opening H1 may have a vertical shape, and the sidewall 23S of the upper opening H2 may have a tapered shape or a slope shape. The height of the lower opening H1 may be shorter than the height of the upper opening H2. The average diameter of the lower opening H1 may be less than the average diameter of the upper opening H2. The shape of the bit line contact holes 23 may be referred to as a dish shape. A first impurity region 19 may be disposed below the bit line contact hole 23. A portion of the first impurity region 19 may be recessed while the bit line contact hole 23 is formed. The upper portion of the upper opening H2 of the bit line contact holes 23 may be provided by the hard mask layer 14. The sidewall of the hard mask layer 14 may have a tapered shape or a slope shape.

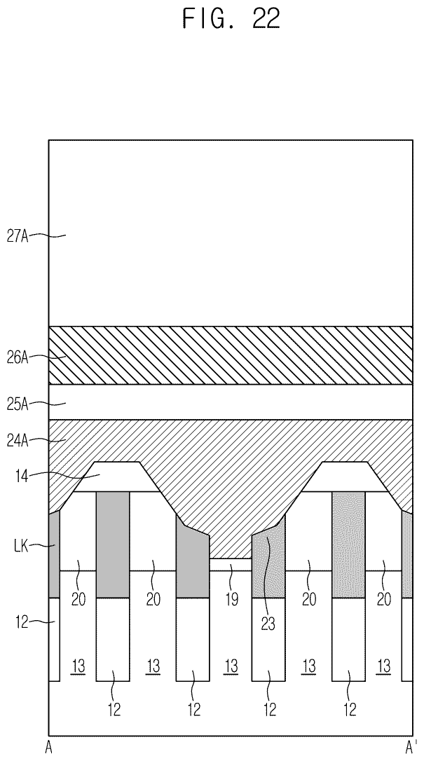

Referring to FIG. 22, a plug layer 24A may be formed over the hard mask layer 14 and the buried word line structure BWL while filling the bit line contact hole 23. For example, the plug layer 24A may include polysilicon.

A bit line barrier layer 25A, a bit line conductive layer 26A, and a bit line hard mask layer 27A may be sequentially formed over the plug layer 24A. The bit line barrier layer 25A and the bit line conductive layer 26A may include a metal-containing material. The bit line barrier layer 25A and the bit line conductive layer 26A may include a metal, a metal nitride, a metal silicide, or a combination thereof. According to an embodiment of the present disclosure, the bit line barrier layer 25A may include titanium nitride, and the bit line conductive layer 26A may include tungsten (W). The bit line hard mask layer 27A may include silicon oxide or silicon nitride. According to an embodiment of the present disclosure, the bit line hard mask layer 27A may be formed of silicon nitride.

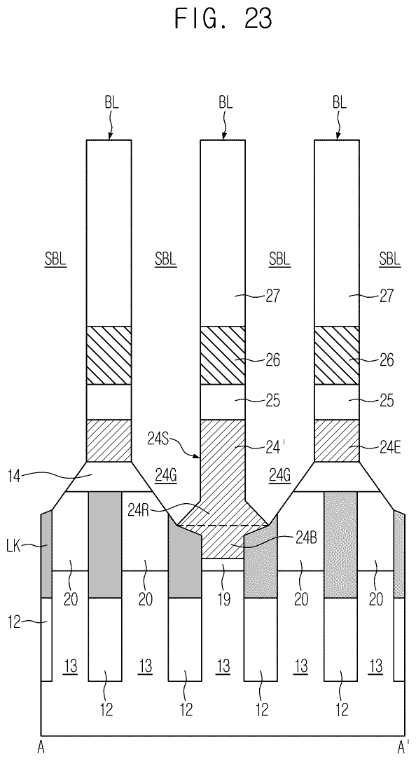

Referring to FIG. 23, a line structure including a first conductive pattern, i.e., a bit line structure BL, may be formed. A line-shaped opening SBL may be defined between the neighboring bit line structures BL. The line-shaped opening SBL may be parallel to the bit line structures BL. The upper surfaces of the hard mask layer 14 and the buried word line structure BWL may be exposed by the line-shaped opening SBL.

The bit line structure BL may include a stack of a bit line contact plug 24, a bit line barrier 25, a bit line 26, and a bit line hard mask 27. The bit line contact plug 24, the bit line barrier 25, the bit line 26, and the bit line hard mask 27 may be formed by an etching process using a bit line mask layer (not shown). In the bit line structure BL, the first conductive pattern may include the bit line 26.

The bit line hard mask layer 27A, the bit line conductive layer 26A, and the bit line barrier layer 25A may be etched by using the bit line mask layer (not shown) as an etching barrier. As a result, the bit line barrier 25, the bit line 26, and the bit line hard mask 27 may be formed. The bit line hard mask 27 may be formed by etching the bit line hard mask layer 27A. The bit line 26 may be formed by etching the bit line conductive layer 26A. The bit line barrier 25 may be formed by etching the bit line barrier layer 25A.

Subsequently, the plug layer 24A below the bit line barrier 25 may be etched. As a result, a bit line contact plug 24′ may be formed. The bit line contact plug 24′ may be formed over the first impurity region 19. The bit line contact plug 24′ may interconnect the first impurity region 19 and the bit line barrier 25 to each other. The bit line contact plug 24′ may be formed in the bit line contact hole 23. The average diameter of the bit line contact plug 24′ may be less than the average diameter of the bit line contact hole 23. Therefore, a gap 24G may be defined in the peripheral area of the bit line contact plug 24′.

The bit line contact plug 24′ may include extended portions 24E, and the extended portions 24E may be disposed in the upper portion of the hard mask layer 14. Accordingly, the bit line contact plug 24′ may extend in a direction that the bit line 26 extends while filling the bit line contact hole 23.

The sidewall 24S of the bit line contact plug 24′ may have a non-vertical shape. For example, the sidewall 24S of the bit line contact plug 24′ may have a tapered shape or a slope shape. The bit line contact plug 24′ may have different diameters according to the height direction. For example, the diameter of the bottom portion 24B of the bit line contact plug 24′ may be the largest, and the diameter may gradually decrease according to the height. The lower portion of the gap 24G may be disposed in the peripheral area of the bottom portion 24B of the bit line contact plug 24′.

A landing portion 24R may be further formed over the bottom portion 24B of the bit line contact plug 24′. The bottom portion 24B and the landing portion 24R may each have a dish shape and may be facing each other vertically. A combination of the bottom portion 24B and the landing portion 24R may define six inflection points.

As described above, a gap 24G may be formed in the bit line contact hole 21 by forming the bit line contact plug 24′. This is because the bit line contact plug 24′ is formed by being etched to have a smaller diameter than the diameter of the bit line contact hole 23. The gap 24G may not be of a surrounding shape that surrounds the bit line contact plug 24′, but may be independently formed on both sidewalls of the bit line contact plug 24′. After all, one bit line contact plug 24′ and a pair of gaps 24G may be disposed in the bit line contact hole 23, and the pair of gaps 24G may be separated by the bit line contact plug 24′. The bottom surface of the gap 24G may extend into the inside of the isolation layer 12. The bottom surface of the gap 24G may be disposed at a lower level than the recessed upper surface of the first impurity region 19. According to another embodiment of the present disclosure, from the perspective of a top view, the gap 24G may have a surrounding shape that surrounds the bit line contact plug 24′.

A structure including the bit line contact plug 24′, the bit line barrier 25, the bit line 26, and the bit line hard mask 27 that are stacked in the mentioned order may be referred to as a bit line structure BL. From the perspective of a top view, the bit line structure BL may be a line-shaped pattern structure extending in the second direction D2.

A line-shaped opening SBL may be defined between the neighboring bit line structures BL. The line-shaped opening SBL may be parallel to the bit line structures BL. The upper surfaces of the hard mask layer 14 and the buried word line structures BWL may be exposed by the line-shaped opening SBL.

Subsequently, a series of the processes illustrated in FIGS. 11 to 19 may be performed.

According to an embodiment of the present disclosure, it is possible to prevent current leakage because the gap between the bit line contact plug and the storage contact plug is sufficient.

According to an embodiment of the present disclosure, the increase in the contact resistance may be compensated for by increasing the line width of the bottom portion of the bit line contact plug.

While the present disclosure has been described with respect to the specific embodiments, it will be apparent to those skilled in the art that various changes and modifications may be made without departing from the spirit and scope of the disclosure as defined in the following claims. Furthermore, the embodiments may be combined to form additional embodiments.

What is claimed is:

1. A semiconductor device comprising:
a first contact structure disposed over a substrate, the first contact structure having a multi-tapered sidewall;
a line structure including a conductive line disposed over the first contact structure; and
a plurality of second contact structures disposed between the line structures.

2. The semiconductor device of claim 1,
wherein the multi-tapered sidewall of the first contact structure has at least one inflection point where a slope of the multi-tapered sidewall changes, and
wherein the at least one inflection point is disposed at a higher level than a bottom surface of the second contact structure.

3. The semiconductor device of claim 1,
wherein the first contact structure contacts the substrate,
wherein the first contact structure includes lower and upper buried portions, and
wherein a width of the upper buried portion is less than a width of the lower buried portion.

4. The semiconductor device of claim 1, wherein the first contact structure includes:
a bottom portion contacting an upper surface of the substrate and having a first tapered sidewall;
a middle portion disposed over the bottom portion and having a second tapered sidewall; and
a top portion disposed over the middle portion and having a vertical sidewall.

5. The semiconductor device of claim 4, wherein a slope of the first tapered sidewall and a slope of the second tapered sidewall are different from each other.

6. The semiconductor device of claim 4, wherein a slope of the second tapered sidewall is closer to approximately 90° than a slope of the first tapered sidewall.

7. The semiconductor device of claim 4, wherein a first inflection point between the first tapered sidewall and the second tapered sidewall is disposed at a level which is higher than a bottom surface of the second contact structure.

8. The semiconductor device of claim 7, wherein a second inflection point between the second tapered sidewall and the vertical sidewall is disposed at a level which is higher than the bottom surface of the second contact structure and the first inflection point.

9. A semiconductor device comprising:
a first impurity region disposed in a substrate;
a second impurity region disposed in the substrate and spaced apart from the first impurity region;
a bit line contact plug disposed over the first impurity region and having a multi-tapered sidewall; and
a storage contact plug disposed over the second impurity region,
wherein the multi-tapered sidewall of the bit line contact plug includes at least one inflection point at which a slope changes, and
wherein the at least one inflection point is disposed higher than a bottom surface of the storage contact plug.

10. The semiconductor device of claim 9, wherein the first contact structure contacts the substrate,
wherein the first contact structure includes lower and upper buried portions, and
wherein a width of the upper buried portion is less than a width of the lower buried portion.

11. The semiconductor device of claim 9, wherein the bit line contact plug includes:
a bottom portion contacting an upper surface of the substrate and having a first tapered sidewall;
a middle portion formed over the bottom portion and having a second tapered sidewall; and
a top portion formed over the middle portion and having a vertical sidewall.

12. The semiconductor device of claim 11, wherein a slope of the first tapered sidewall and a slope of the second tapered sidewall are different from each other.

13. The semiconductor device of claim 11, wherein a slope of the second tapered sidewall is closer to approximately 90° than a slope of the first tapered sidewall.

14. The semiconductor device of claim 11, wherein a first inflection point between the first tapered sidewall and the second tapered sidewall is disposed at a level which is higher than the bottom surface of the storage contact plug.

15. The semiconductor device of claim 14, wherein a second inflection point between the second tapered sidewall and the vertical sidewall is disposed at a level which is higher than a bottom surface of a second contact structure and the first inflection point.

16. A method for fabricating a semiconductor device, the method comprising:
forming a first impurity region and a second impurity region in a substrate;
forming a bit line contact hole that exposes the first impurity region and has a multi-tapered sidewall;
forming a bit line contact plug that fills the bit line contact hole and includes a lower buried portion contacting the first impurity region and an upper buried portion over the lower buried portion;
forming a gap-fill layer in a peripheral area of the lower buried portion of the bit line contact plug;
side-recessing a sidewall of the upper buried portion of the bit line contact plug; and
forming a storage contact plug that contacts the second impurity region.

17. The method of claim 16, wherein forming the bit line contact hole that exposes the first impurity region and has the multi-tapered sidewall includes:
forming a sacrificial hard mask layer over the substrate;
forming a mask pattern having a mask level opening over the sacrificial hard mask layer;
performing a first etching process of forming a recessed opening having a tapered sidewall in a portion of the sacrificial hard mask layer;
performing a second etching process of converting the recessed opening into a dish-shaped recessed opening; and
performing a third etching process of transferring the dish-shaped recessed opening to the substrate.

18. The method of claim 17, wherein the second etching process includes isotropic etching.

19. The method of claim 16, wherein the bit line contact plug includes:
a bottom portion contacting an upper surface of the substrate and having a first tapered sidewall;
a middle portion formed over the bottom portion and having a second tapered sidewall; and
a top portion formed over the middle portion and having a vertical sidewall,
wherein a slope of the second tapered sidewall is closer to approximately 90° than a slope of the first tapered sidewall.

20. The method of claim 19, wherein a first inflection point between the first tapered sidewall and the second tapered sidewall is disposed at a level which is higher than a bottom surface of the storage contact plug, and
a second inflection point between the second tapered sidewall and the vertical sidewall is disposed at a level which is higher than the bottom surface of the storage contact plug and the first inflection point.

21. The method of claim 19, further comprising:
after performing the second etching process,
forming a buffer spacer over the dish-shaped recessed opening.
